(19) United States
(12) Patent Application Publication
(10) Pub. No.: US 2017/0186949 A1
(43) Pub. Date: Jun. 29, 2017

(54) FILM FORMING DEVICE AND METHOD

(71) Applicants: BOE TECHNOLOGY GROUP CO., LTD., Beijing (CN); HEFEI BOE OPTOELECTRONICS TECHNOLOGY CO., LTD., Anhui (CN)

(72) Inventor: Yangkun JING, Beijing (CN)

(73) Assignees: BOE TECHNOLOGY GROUP CO., LTD., Beijing (CN); HEFEI BOE OPTOELECTRONICS TECHNOLOGY CO., LTD., Anhui (CN)

(21) Appl. No.: 15/320,494

(22) PCT Filed: Mar. 14, 2016
(86) PCT No.: PCT/CN2016/076263

§ 371 Date: Dec. 20, 2016

(30) Foreign Application Priority Data
Apr. 7, 2015 (CN) 201510161261.6

(51) Int. Cl. H01L 51/00; C23C 14/54; H01L 51/56; C23C 14/12

(52) U.S. Cl. CPC H01L 51/0002; C23C 14/12; C23C 14/542; H01L 51/56

(57) ABSTRACT

A film-forming device and a film forming method are provided. The film-forming device is configured to form an organic material thin film at a target region of a substrate and includes a gas supplying mechanism and a gas injection mechanism. The gas supplying mechanism is configured to import a mixture gas of organic material steam and an inert gas into the gas injection mechanism. The gas injection mechanism is configured to inject the mixture gas from the gas supplying mechanism onto the target region of the substrate.

### CROSS-REFERENCE TO RELATED APPLICATIONS

This application claims a priority to Chinese Patent Application No. 201510161261.6 filed on Apr. 7, 2015, the disclosures of which are incorporated in their entirety by reference herein.

### TECHNICAL FIELD

The present disclosure relates to the field of material processing, and in particular to a film forming device and a film forming method.

### BACKGROUND

Organic materials are becoming more and more popular in the field of optical element production. The cost of the optical element production using the organic material is lower than that using the inorganic material. In addition, the organic material is very applicable to the specific application such as flexible substrate due to its inherent property, e.g., the flexibility. The organic optical element includes the organic light-emitting diode (OLED), the organic photosensitive transistor, the organic photovoltaic cell and the organic optical detector. For the OLED, the organic material has better performance than the ordinary material. For example, a wave length of light emitted by an organic light-emitting layer may be adjusted by using an appropriate dopant.

The early organic material deposition method includes depositing an organic material by a mask. The organic material may be deposited by a mask which is integrated with a base substrate or deposited by a mask which is not integrated with the base substrate. However, a resolution achieved by adopting the mask may be limited by a resolution which can be achieved by the mask, an accumulation of the organic material on the mask, a diffusion of the organic material on the base substrate and the like.

In the related art, the organic material is deposited on the substrate and forms a film thereon by evaporation or an organic vapor jet deposition (OVJP). Both the two methods have disadvantages. Affected by a distance between an evaporator source and a substrate and an area of the substrate and the like, it is only able to form a film on a relative small substrate by evaporation, and a temperature of the evaporator source needs to be increased when a film-forming rate is increased, which may change the physicochemical property of the organic material. According to the OVJP, a colloidal organic material is injected onto a target region of a substrate, therefore it is not easy to control an injection pressure, a thickness of the formed film and a film-forming rate, and the thickness of the formed film may be nonuniform.

### SUMMARY

In view of this, a film-forming device and a film forming method are provided in the present disclosure, which are applicable to substrates of most sizes and by which it is easy to control a film forming process.

A film-forming device is provided and is configured to form an organic material thin film at a target region of a substrate. The film-forming device includes a gas supplying mechanism and a gas injection mechanism. The gas supplying mechanism is configured to import a mixture gas of organic material steam and an inert gas into the gas injection mechanism. The gas injection mechanism is configured to inject the mixture gas from the gas supplying mechanism onto the target region of the substrate.

Optionally, the gas supplying mechanism includes an inert gas transport pipe, an organic material evaporator source and a mixture gas transport pipe. The inert gas transport pipe is configured to import the inert gas; and the mixture gas transport pipe is configured to import the mixture gas of the inert gas and the organic material steam generated by the organic material evaporator source into the gas injection mechanism.

Optionally, the film-forming device further includes a device body provided with a cavity therein. The gas injection mechanism includes a pushrod for driving gas; the pushrod for driving gas is inserted into the cavity of the device body through a first hole in the device body; the mixture gas transport pipe is in communication with the cavity of the device body via a second hole in the device body, and a valve is arranged at a connection position of the mixture gas transport pipe and the cavity of the device body; the valve defines a gas storage space within the cavity of the device body; and a heating mechanism is in the gas storage space.

Optionally, there exists a plurality of mixture gas transport pipes.

Optionally, the device body includes a straight channel configured to receive the pushrod for driving gas and a gas exit at an end of the straight channel; the pushrod for driving gas includes a screwed flange on a circumference surface thereof neighboring the gas exit, and a head at an end of the screwed flange; the head matches with a shape of the gas exit.

Optionally, a sealing element is arranged at the first hole; a hole enlargement portion is provided at a portion of the first hole, and the portion of the first hole is adjacent to both of the sealing element and the gas storage space.

Optionally, the pushrod for driving gas includes a first rod and a second rod; the second rod is provided with the screwed flange at one end thereof, and the other end thereof is connected to the first rod; and a diameter of the first end is larger than a diameter of the second rod.

Optionally, the gas injection mechanism further includes a rotation electric motor configured to drive the pushrod for driving gas.

Optionally, the gas injection mechanism is a piezoelectric pump.

Furthermore, a film forming method is provided and includes: using the above film-forming device to inject a mixture gas of organic material steam and an inert gas onto a target region of a substrate, thereby depositing the organic material on the target region of the substrate.

Optionally, a flow rate of the mixture gas at a preliminary stage of an organic material deposition process is smaller than a flow rate of the mixture gas at a middle stage of the organic material deposition process.

Optionally, by the film-forming device hereinabove, a mixture gas of organic material steam and an inert gas is injected onto a target region of a substrate and the pushrod for driving gas is rotated back and forth repeatedly when a deposition process is completed.

Optionally, a rotation speed at which the pushrod for driving gas is rotated back and forth repeatedly, is such a value that the mixture gas is sealed within the gas storage space when the deposition process is completed.

From the above, according to the film-forming device and method provided in the present disclosure, the organic material steam and the inert gas are mixed and then injected onto the target region of the substrate to form a film thereon, such that it is easy to control the deposition rate of the organic material and the uniformity of the organic material film. The film-forming device and method are applicable to the substrates of different sizes and the organic material gases of different viscosities. In addition, according to the film-forming device and method in the embodiments of the present disclosure, the deposition rate of the organic material may be increased without increasing the temperature of the mixture gas, and the sealing of the mixture gas may be guaranteed and the service life of the sealing element may be increased.

### BRIEF DESCRIPTION OF THE DRAWINGS

FIG. 1 is a schematic view of a film-forming device in some embodiments of the present disclosure;

FIG. 2 is a top view of a film-forming device in some embodiments of the present disclosure;

FIG. 3 is a schematic view of a hole enlargement portion in some embodiments of the present disclosure;

FIG. 4 is a schematic view of a pushrod for driving gas in some embodiments of the present disclosure;

FIG. 5 is similar to FIG. 1, where the film-forming device further includes a sealing element, a driving mechanism and a heating mechanism;

FIG. 6 is similar to FIG. 2, where an inert gas transport pipe and an organic material evaporator source are further provided; and

FIG. 7 is a schematic view of a film-forming device in some embodiments of the present disclosure.

### DETAILED DESCRIPTION

In order to make the objects, the technical solutions and the advantages of the present disclosure more apparent, the present disclosure will be described hereinafter in conjunction with the drawings and embodiments.

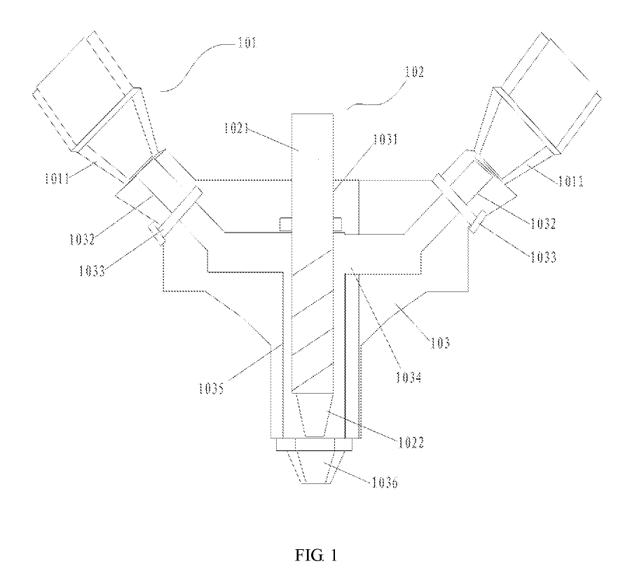

As shown in FIG. 1, a film-forming device is provided in some embodiments of the present disclosure, which is configured to form an organic thin film at a target region of a substrate. The film-forming device includes a gas supplying mechanism 101 and a gas injection mechanism 102.

The gas supplying mechanism 101 is configured to import a mixture gas of organic material steam and an inert gas into the gas injection mechanism 102. The gas injection mechanism 102 is configured to inject the mixture gas from the gas supplying mechanism onto the target region of the substrate.

It can be seen from the above, according to the film-forming device provided in the embodiments of the present disclosure, the mixture gas of the organic material steam and the inert gas is injected onto the target region of the substrate, so as to form a film of the organic material thereon. By adjusting a size of a gas exit of the gas injection mechanism 102, it is able to control an area of a region of the substrate onto which the mixture gas is injected, and an area of the formed film may be enlarged by increasing an amount of gas injection points, so the film-forming device is applicable to the substrates of different sizes. In addition, the mixture gas of the organic material steam and the inert gas is injected onto the target region of the substrate to form a film thereon, so the size of the gas injection point may be controlled by adjusting the size of the gas exit of the gas injection mechanism 102, and then it is not necessary to increase an interval between the gas injection mechanism 102 and the substrate to make a thickness of the formed film to be uniform. Moreover, it is easy to control a concentration, uniformity and an injection rate of the mixture gas, and a film-forming process control may be easier.

According to the OVJP of the related art, a mixture of a colloidal organic material and an inert gas is printed to from a film, such that it is difficult to control a thickness and uniformity of the formed film and the colloidal organic material is prone to adhere onto the transport pipe in the film-forming process. In compared with the OVJP of the related art, the gas is of a strong flowability, and the gas, if not liquefied, is not prone to adhere onto the transport pipe, therefore the colloidal material adhesion in the related art may be avoided.

In some embodiments of the present disclosure, a temperature of the inert gas is high, and the organic material steam is carried by the high-temperature inert gas and the mixture thereof is injected onto the target region of the low-temperature substrate, and then the organic material steam is absorbed by the substrate and deposited thereon. A rate of forming a film by deposition, which may be in Å/s scale, may be controlled by adjusting the gas injection rate, without increasing the temperature of the organic material steam or the inert gas for the purpose of increasing the rate of forming a film by deposition, therefore a molecular structure of the organic material may not be damaged due to the high temperature.

In some embodiments of the present disclosure, the organic material steam by be generated by an organic material evaporator source, and the gas injection mechanism may be any pump applicable to the present disclosure.

In some embodiments of the present disclosure, the inert gas may be a rare gas in terms of chemistry, or a gas such as nitrogen which is not prone to react with other materials at a normal or a high temperature, or a gas which is not prone to react with the organic material steam in the present disclosure. The mixture gas may be compressed prior to being imported into the gas injection mechanism 102 by the gas supplying mechanism 101. Therefore, a thrust of the mixture gas injected from the gas injection mechanism 102 may be a sum of a thrust of the gas injection mechanism 102 and an air pressure of the compressed mixture gas.

Optionally, the gas supplying mechanism 101 imports the mixture gas at such a pressure that the mixture gas may not lead from the gas injection mechanism 102 when the gas injection mechanism 102 does not inject the mixture gas and the gas injection mechanism 102 is in communication with the gas supplying mechanism 101.

According to the film-forming device in the embodiments of the present disclosure, the organic material steam may be carried by an inert gas of a small molecule weight (e.g., nitrogen) and accelerated, such that the film deposited on the substrate may be compact, ordered and of high quality.

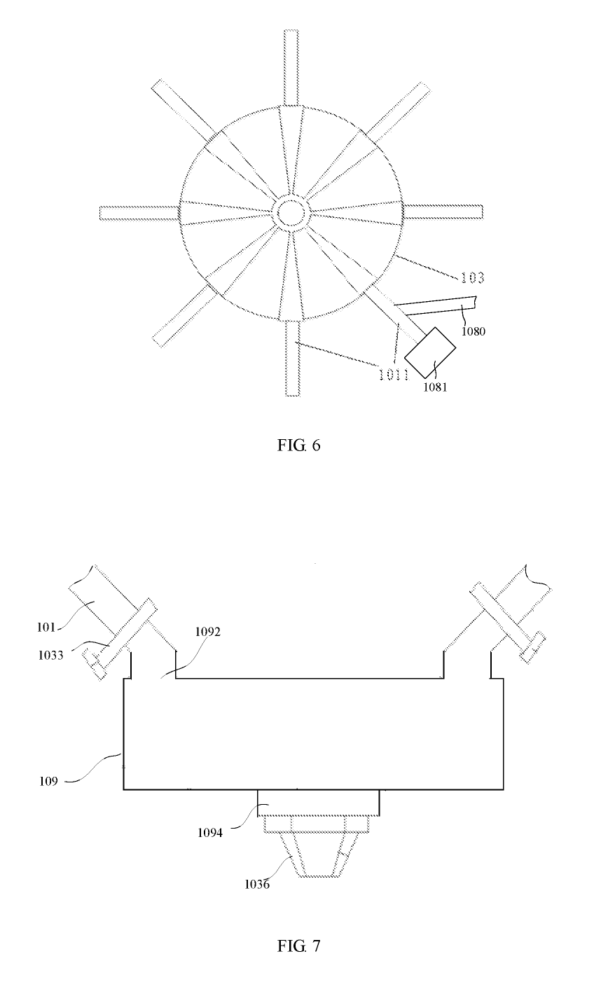

In some embodiments of the present disclosure, as shown in FIG. 6, the gas supplying mechanism 101 includes an inert gas transport pipe 1080, an organic material evaporator source 1081 and a mixture gas transport pipe 1011. The inert gas is imported via the inert gas transport pipe 1080, and the mixture gas of the inert gas and the organic material steam generated by the organic material evaporator source 1081 is imported into the gas injection mechanism 102 via the mixture gas transport pipe 1011. In some embodiments of the present disclosure, the inert gas transport pipe 1080 may be a pipe for transporting the inert gas from an inert gas source to the mixture gas transport pipe 1011. The organic material evaporator source may be the one applied in the evaporation of the related art.

In some embodiments of the present disclosure, the gas supplying mechanism 101 may be provided with a control element which is configured to control the import of the mixture gas based on an injection rate of the mixture gas of the gas injection mechanism 102.

In some embodiments of the present disclosure, the film-forming device further includes a device body 103 provided with a cavity therein. The gas injection mechanism 102 is provided with a pushrod for driving gas 1021. The pushrod for driving gas 1021 is inserted into the cavity of the device body 103 through a first hole 1031 of the device body 103. The mixture gas transport pipe 1011 is in communication with the cavity of the device body 103 via a second hole 1032 of the device body 103. A valve 1033 is arranged at a connection position of the mixture gas transport pipe 1011 and the cavity of the device body 103. The valve 1033 defines a gas storage space 1034 within the cavity of the device body 103. A heating mechanism is arranged in the gas storage space 1034.

In some embodiments of the present disclosure, as shown in FIG. 5, the heating mechanism 1083 may be any heating mechanism applicable to the gas storage space 1034, so as to hold a temperature of the mixture gas stored in the gas storage space 1034, improve a uniformity of the mixture gas and avoid a liquidation of the organic material steam.

In some embodiments of the present disclosure, the valve 1033 is an electronic-control valve. When the gas injection mechanism 102 injects the mixture gas outwards or the deposition of the film is completed, the valve 1033 is closed. When the gas supplying mechanism 101 imports the mixture gas into the gas injection mechanism 102, the valve 1033 is opened.

Optionally, the mixture gas transport pipe 1011 may be arranged at an appropriate position, such that the mixture gas, which is imported into the cavity of the device body 103 via the second hole 1032, may be imported in a direction perpendicular to the pushrod for driving gas 1021.

Those skilled in the art may understand that, the gas injection mechanism 102 may further be provided with necessary driving mechanisms, such as an electric motor 1086 shown in FIG. 6 and the like.

An injection rate of the mixture gas may be controlled by the pushrod for driving gas 1021.

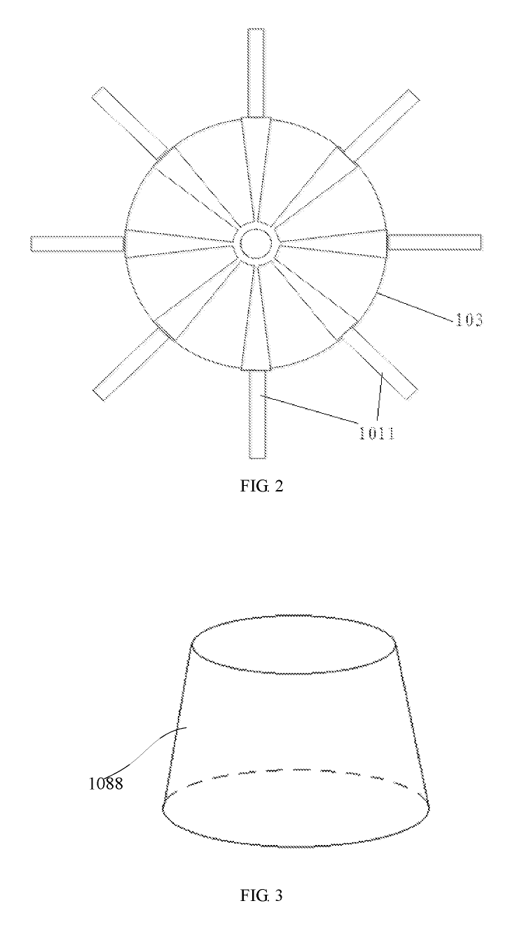

In some embodiments of the present disclosure, there may be a plurality of mixture gas transport pipes 1011. As shown in FIG. 2, each kind of the mixture gases including different kinds of organic material steam may be imported via a corresponding mixture gas transport pipe 1011, such that it is able to deposit various organic materials on the substrate by one film-forming device, thereby improving a utilization rate of the film-forming device.

When there is a plurality of mixture gas transport pipes 1011, a plurality of valves may be arranged correspondingly to control the transport of the mixture gases including different kinds of organic material steam. In the process of forming a film by deposition, when the mixture gas is imported via a certain mixture gas transport pipe 1011, the valves of the mixture gas transport pipes 1011 other than the certain mixture gas transport pipe 1011 may be closed.

In some embodiments of the present disclosure, the device body 103 includes a straight channel 1035 configured to receive the pushrod for driving gas 1021 and a gas exit 1036 arranged at an end of the straight channel 1035. The pushrod for driving gas 1021 is provided with a screwed flange 1025 on a circumference surface thereof adjacent to the gas exit 1036, and a head 1022 is arranged at an end of the screwed flange 1025 and matched with a shape of the gas exit 1036.

Optionally, the gas injection mechanism 102 further includes a rotation electric motor 1086 (referring to FIG. 5) configured to drive the pushrod for driving gas 1021, so as to stir the mixture gas by rotating the screwed flange of the pushrod for driving gas 1021 and inject the mixture gas through the gas exit 1036.

By adjusting the interval between the pushrod for driving gas 1021 and the device body 103, a flute pitch of the screwed flange and a size of an opening of the gas exit 1036, it is able to inject the mixture gases including the organic materials of different viscosities and deposit the organic materials to form different films.

In some embodiments of the present disclosure, the second hole 1032 is level with the screwed flange when the entire pushrod for driving gas 1021 is retracted within the gas storage space 1034, thereby improving a flowability of the mixture gas at the second hole 1032.

Because the mixture gas may be injected onto the target region of the substrate in a collimated manner, a value of a pressure applied to the mixture gas in the injection process may be of a relative wide range, and the rate of forming a film by deposition may also be adjusted in a relative wide range. Due to the gas exit 1036 and the straight channel 1035, it is able to ensure that the mixture gas is injected in a collimated manner. The film-forming device in the embodiments of the present disclosure may be applied to the substrates of any size and shape to form a film thereon by deposition.

A typical OLED organic film has a thickness in Å/s scale, which may be formed by using nozzles that are arranged linearly. Each nozzle corresponds to a gas exit and is capable of controlling the gas injection rate to be in Å/s scale. Meanwhile, when a diameter of each nozzle is matched with a width of a pixel, it is able to form a film on a display substrate by deposition in a short time. In some embodiments of the present disclosure, a micromolecular organic material is applied, since the micromolecular organic material has a sufficient steam pressure at a low temperature and is easy to be deposited at a high rate, and that is the reason why the micromolecular organic material is applied in the OVJP of the related art. However, the film-forming device in the embodiments of the present disclosure is applicable to various materials such as polymer.

When the injection rate of the mixture gas is high enough, a so-called jet flow is formed, and that is different from the other technologies such as organic vapor phase deposition (OVPD) which applies a carrier gas without jet flow.

Those skilled in the art may understand that, the gas injection mechanism 102 includes necessary driving mechanisms. In some embodiments of the present disclosure, the pushrod for driving gas 1021 may be driven by a rotation electric motor. By rotating the pushrod for driving gas 1021, the screwed flange thereof drives the mixture gas to flow, and then the mixture gas is injected through the gas exit 1036. In compared with the way of straight pushing the mixture gas, according to the film-forming device in the present disclosure, the mixture gas is spirally pushed out of the gas exit 1036, and the flow rate of the mixture gas through the gas exit 1036 may be adjusted by controlling a rotation rate of the pushrod for driving gas 1021, such that a flow rate of the mixture gas may maintain constant in a relative long period. Further, it is easier to control the rotation rate of the pushrod for driving gas 1021 than to control a translational speed thereof.

In some embodiments of the present disclosure, the nozzle defining the gas exit 1036 may be replaceable, such that it is able to adjust the size of pixels corresponding to the formed film by adjusting the size of the gas exit 1036, and it is able to improve the resolution corresponding to the formed film by reducing the size of the gas exit 1036. Therefore, it is able to print an organic film layer onto the substrate directly without a mask. A contact area of the mixture gas and the substrate may be adjusted by adjusting the size of the gas exit 1036. When the contact area of the mixture gas and the substrate is small enough, the uniformity of the deposited organic material may achieve a predetermined value, and thus there is no need to increase the interval between the gas exit and the substrate for the purpose of improving the uniformity of the deposited organic material film. As such, the film-forming device in the embodiments of the present disclosure may deposit the organic material onto the substrate of any size.

In some embodiments of the present disclosure, a sealing element is arranged at the hole. A hole enlargement portion 1088 is provided at a portion of the hole, and the portion of the hole is adjacent to both of the sealing element and the gas storage space 1034. The sealing element 1087 is shown in FIG. 5.

To increase a flow resistance of a space for blocking stream, it is necessary to arrange the sealing element to guarantee a gas tightness of the gas storage space 1034 and the pushrod for driving gas 1021. By maintaining the gas tightness of the sealing element and the pushrod for driving gas 1021, when the mixture gas rises along the first hole 1031 due to a decreasing of the gas pressure, the gas pressure in the space for blocking stream may be increased, and then, due to the sealing element, the mixture gas may not leak through the first hole 1031.

Generally, the hole has a small diameter and a certain extending length, and then capillarity of the gas may occur at the hole and the gas may leak through the hole as a result, and that is to the disadvantage of the gas sealing. Therefore, in addition to the sealing element arranged at the hole, the hole enlargement portion 1088 is arranged in the hole at a portion which is adjacent to both of the sealing element and the gas storage space 1034. The hole includes the first hole 1031, the second hole 1032 and other holes which may be probably provided in the device body 103.

In an optional embodiment, as shown in FIG. 3, the hole includes the first hole 1031. The interval between the pushrod for driving gas 1021 and the first hole 1031 may be very small, and the mixture gas may rise in the interval between the pushrod for driving gas 1021 and the first hole 1031 due to capillarity action. The presence of the hole enlargement portion 1088 can enlarge the interval between the pushrod for driving gas 1021 and the first hole 1031, so as to prevent the mixture gas from rising in the interval between the pushrod for driving gas 1021 and the first hole 1031. In some embodiments of the present disclosure, as shown in FIG. 3, the hole enlargement portion 1088 has a mortar-like shape, i.e., a conical trapezoid shape.

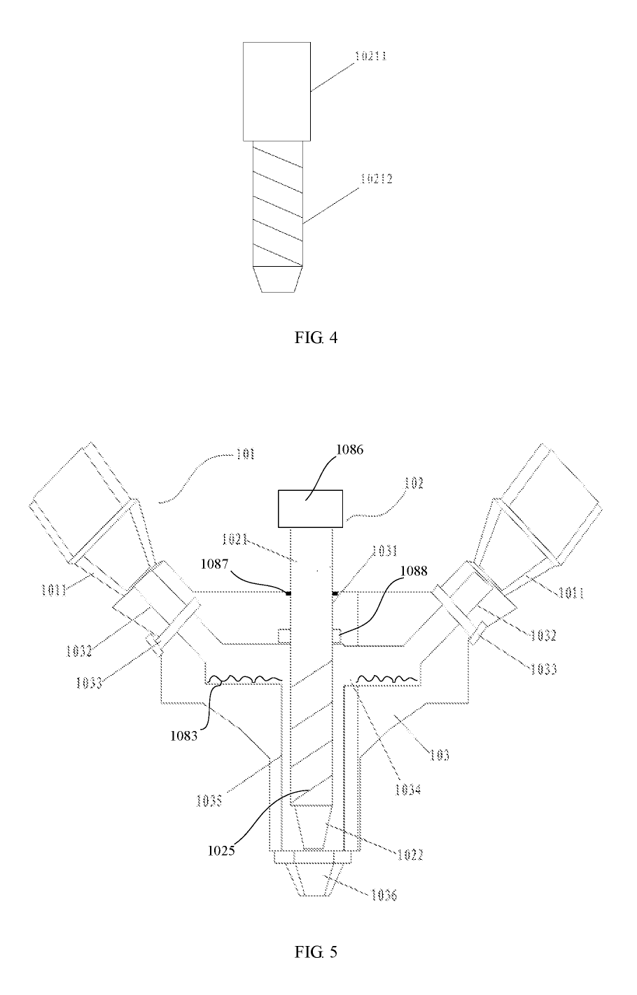

In addition, the pushrod for driving gas 1021 may include a second rod 10212 provided with the screwed flange and a first rod 10211 connected to an end of the second rod 10212 away from the screwed flange. The first rod 10211 has a large diameter, and the second rod 10212 has a small diameter. As shown in FIG. 4, the pushrod for driving gas 1021 may be manufactured in an integrative way.

In some embodiments of the present disclosure, a sealing element needs to be arranged at any position of the device body 103 where a gas leakage may occur. In addition, the device body 103 may be manufactured in an integrative way, thereby reducing a quantity of elements in contact with the steam and reducing a quantity of the portions of the device body 103 where the sealing elements are arranged, so as to reduce a quantity of the sealing elements which are easy to loss.

If the pushrod for driving gas 1021 moves back and forth to push outwards the mixture gas, the service life of the sealing element may be reduced. In some embodiments of the present disclosure, the mixture gas is injected by rotating the pushrod for driving gas 1021, thereby reducing a frictional loss between the sealing element and the pushrod for driving gas 1021 and prolonging the service life of the sealing element.

In some embodiments of the present disclosure, as shown in FIG. 7, the gas injection mechanism is a piezoelectric pump 109. The piezoelectric pump 109 is provided with an entrance 1092 and an exit 1094. The gas supplying mechanism 101 is connected to the entrance 1092, so as to transport the mixture gas of the inert gas and the organic material steam to the gas injection mechanism, i.e., the piezoelectric pump 109. The gas exit 1036 is in communication with the exit 1094, so as to inject the mixture gas onto the target region of the substrate.

Moreover, a film forming method is provided in some embodiments of the present disclosure, which includes: using the film-forming device hereinabove to transport a mixture gas of organic material steam and an inert gas to a target region of a substrate, thereby depositing the organic material on the target region of the substrate.

In compared with other methods such as ink jet printing, according to the film forming method provided in the present disclosure, a mixture gas of organic material steam and an inert gas is injected on to a target region of a substrate to form a film thereon by deposition, such that it is able to form a film by deposition on a substrates of any size and shape. In most situations, the organic material, after being gasified, is still stable. Meanwhile, according to the present disclosure, a rate of the film forming by deposition may be adjusted by controlling an injection rate of the mixture gas, and an injection pressure of the mixture gas may be adjusted, therefore there is no need to increase a temperature of the organic material steam, the inert gas or a mixture thereof for purpose of increasing the rate of the film forming by deposition, such that the organic material may not be damaged due to high temperature during the deposition.

In some embodiments of the present disclosure, a flow rate of the mixture gas at a preliminary stage of an organic material deposition process is smaller than a flow rate of the mixture gas at a middle stage of the organic material deposition process.

At the very beginning of the mixture gas injection, the gas flow is not steady and a gas injection resistance is low, so the pushrod for driving gas may inject the mixture gas at a relative low rate. After the gas flow becomes steady, the gas injection resistance may become high, so the pushrod for driving gas may inject the mixture gas at a relative high rate in the injection and deposition process. Meanwhile, at the beginning of importing the mixture gas into the second hole, the gas supplying mechanism may push the mixture gas at a low pressure, so as to protect the sealing element, the nozzle or the like from being damped due to a low flow resistance of the mixture gas at a lower portion of the gas storage space.

In some embodiments of the present disclosure, the film-forming device injects the mixture gas of the organic material steam and the inert gas onto a target region of the substrate. When the deposition is completed, the pushrod for driving gas is rotated back and forth repeatedly.

After an injection and deposition process is completed, the film-forming device may maintain standby for a while until the next injection and deposition process is started. When the film-forming device is standby, the pushrod for driving gas may be rotated back and forth repeatedly and slightly, so as to stir the mixture gas in the gas storage space. The mixture gas is stirred so as to maintain flowability thereof, and then the mixture gas may be injected without applying a large pressure on it. The pushrod for driving gas is rotated back and forth in such a range that the liquefied mixture gas may not drip from the nozzle, and the rotation range of the pushrod for driving gas may be determined through experiments. Of course, the mixture gas is not imported into the gas injection mechanism when the film-forming device is standby.

In some embodiments of the present disclosure, a rotation speed at which the pushrod for driving gas is rotated back and forth repeatedly, is such a predetermined value that the mixture gas may be sealed within the gas storage space when the deposition process is completed.

From the above, according to the film-forming device and method provided in the present disclosure, the organic material steam and the inert gas are mixed and then injected onto the target region of the substrate to form a film thereon, such that it is easy to control the deposition rate of the organic material and the uniformity of the organic material film. The film-forming device and method are applicable to the substrates of different sizes and the organic material gases of different viscosities. In addition, according to the film-forming device and method in the embodiments of the present disclosure, the deposition rate of the organic material may be increased without increasing the temperature of the mixture gas, and the sealing of the mixture gas may be guaranteed and the service life of the sealing element may be increased.

It should be appreciated that, the embodiments in the description are for illustrative purposes only, but shall not be used to limit the scope of the present disclosure. The embodiments of the present disclosure and the features described therein may be combined without confliction.

Obviously, a person skilled in the art may make further modifications and improvements without departing from the spirit of the present disclosure, and these modifications and improvements shall also fall within the scope of the present disclosure.

1. A film-forming device for forming an organic material thin film at a target region of a substrate, comprising:
a gas supplying mechanism; and
a gas injection mechanism;
wherein the gas supplying mechanism is configured to import a mixture gas of organic material steam and an inert gas into the gas injection mechanism; and
wherein the gas injection mechanism is configured to inject the mixture gas from the gas supplying mechanism onto the target region of the substrate.

2. The film-forming device according to claim 1, wherein the gas supplying mechanism comprises an inert gas transport pipe, an organic material evaporator source and a mixture gas transport pipe;
wherein the inert gas transport pipe is configured to import the inert gas; and the mixture gas transport pipe is configured to import the mixture gas of the inert gas and the organic material steam generated by the organic material evaporator source into the gas injection mechanism.

3. The film-forming device according to claim 2, further comprising a device body with a cavity therein;
wherein the gas injection mechanism comprises a pushrod for driving gas; the pushrod for driving gas is inserted into the cavity of the device body through a first hole in the device body; the mixture gas transport pipe is in communication with the cavity of the device body via a second hole in the device body, and a valve is arranged at a connection position of the mixture gas transport pipe and the cavity of the device body; the valve defines a gas storage space within the cavity of the device body; and a heating mechanism is in the gas storage space.

4. The film-forming device according to claim 3, comprising a plurality of mixture gas transport pipes.

5. The film-forming device according to claim 3, wherein the device body comprises a straight channel configured to receive the pushrod for driving gas and a gas exit at an end of the straight channel;
the pushrod for driving gas comprises a screwed flange on a circumference surface thereof neighboring the gas exit, and a head at an end of the screwed flange; the head matches with a shape of the gas exit.

6. The film-forming device according to claim 3, wherein a sealing element is arranged at the first hole; a hole enlargement portion is provided at a portion of the first hole, and the portion of the first hole is adjacent to both of the sealing element and the gas storage space.

7. The film-forming device according to claim 5, wherein the pushrod for driving gas comprises a first rod and a second rod;
the second rod is provided with the screwed flange at one end thereof, and the other end thereof is connected to the first rod; and
a diameter of the first end is larger than a diameter of the second rod.

8. The film-forming device according to claim 5, wherein the gas injection mechanism further comprises a rotation electric motor configured to drive the pushrod for driving gas.

9. The film-forming device according to claim 1, wherein the gas injection mechanism is a piezoelectric pump.

10. A film forming method, comprising:
using the film-forming device according to claim 1 to inject a mixture gas of organic material steam and an inert gas onto a target region of a substrate, thereby depositing the organic material on the target region of the substrate.

11. The method according to claim 10, wherein a flow rate of the mixture gas at a preliminary stage of an organic material deposition process is smaller than a flow rate of the mixture gas at a middle stage of the organic material deposition process.

12. A film forming method, comprising:
using the film-forming device according to claim 3 to inject a mixture gas of organic material steam and an inert gas onto a target region of a substrate; and
rotating the pushrod for driving gas back and forth repeatedly when a deposition process is completed.

13. The method according to claim 12, wherein a rotation speed at which the pushrod for driving gas is rotated back and forth repeatedly, is such a value that the mixture gas is sealed within the gas storage space when the deposition process is completed.
